(19) United States
(12) Patent Application Publication
(10) Pub. No.: US 2025/0244385 A1
(43) Pub. Date: Jul. 31, 2025

(54) MONITOR BLOCK, INTERFACE CIRCUIT, AND METHOD OF OPERATING DEBUGGING SYSTEM

(71) Applicant: SAMSUNG ELECTRONICS CO., LTD., SUWON-SI (KR)

(72) Inventors: MINSEONG KIM, SUWON-SI (KR); MINHO CHOI, SUWON-SI (KR)

(21) Appl. No.: 19/024,130

(22) Filed: Jan. 16, 2025

(30) Foreign Application Priority Data
Jan. 26, 2024 (KR) 10-2024-0012664
Apr. 30, 2024 (KR) 10-2024-0058126

(51) Int. Cl. G01R 31/3185

(52) U.S. Cl. CPC G01R 31/31858; G01R 31/318569; G01R 31/318572

(57) ABSTRACT

A serial interface circuit includes an input/output (I/O) port to receive data and a control circuit configured to load a delay metric for the serial interface circuit, transmit first control information of the delay metric to a monitor circuit to cause the monitor circuit to generate a plurality of delay time measurement values, sort the plurality of delay time measurement values to generate sorted values, generate a look-up table (LUT) by mapping the sorted values to indices and transmit the LUT to the monitor circuit.

### CROSS-REFERENCE TO RELATED APPLICATION

This application claims priority under 35 U.S.C. § 119 to Korean Patent Application Nos. 10-2024-0012664, filed on Jan. 26, 2024, and 10-2024-0058126, filed on Apr. 30, 2024, in the Korean Intellectual Property Office, the disclosures of which are incorporated by reference in their entirety herein.

### TECHNICAL FIELD

The present disclosure is directed to inventive concept relates to a monitor block, an interface circuit, and a method of operating a debugging system.

### DISCUSSION OF RELATED ART

A serial interface circuit is an electronic circuit used to transmit and receive data between devices in a serial communication format, where data bits are transmitted sequentially over a single channel or wire, as opposed to parallel communication which uses multiple channel. The serial interface circuit may generate a serial signal by serializing parallel signals input from at least one source and transmit the generated serial signal at high speed to another device through one channel.

However, it is not easy to debug errors that occur in the serial interface circuit due to limitations in its storage space.

### SUMMARY

Embodiments of the inventive concept provides a monitor circuit, an interface circuit, and a method of operating a debugging system using low resolution data. For example, high resolution data such as delay time measurement value(s) are converted into an index or an index history based on a look-up table (LUT), and the resulting index is utilized in a debugging process.

According to an embodiment of the inventive concept, there is provided an serial interface circuit including an input/output (I/O) port configured to receive data and a control circuit configured to load a delay metric for the serial interface circuit, transmit first control information of the delay metric to a monitor circuit to cause the monitor circuit to generate a plurality of delay time measurement values, sort the plurality of delay time measurement values to generate sorted values, generate a look-up table (LUT) by mapping the sorted values to indices and transmit the LUT to the monitor circuit.

According to an embodiment of the inventive concept, there is provided a monitor circuit including a timing generator, an index conversion circuit, a result register, and a control register. The control register configured to drive the timing generator, the index conversion circuit, and the result register based on at least one piece of control information received from a serial interface circuit. When first control information for generating a look-up table (LUT) is received, the control register drives the timing generator according to the first control information to generate a plurality of delay time measurement values and transmits the plurality of delay time measurement values to the serial interface circuit, and stores the LUT received from the serial interface circuit in the index conversion circuit, and the LUT is generated by mapping the plurality of delay time measurement values to indices.

According to an embodiment of the inventive concept, there is provided a method of operating a debugging system, the method including generating a look-up table (LUT) based on a first delay element, when an error occurs in a target block, measuring at least one delay time in the target block and generating a delay time measurement value based on the measured at least one delay time, converting the delay time measurement value into an index based on the LUT, and debugging an error based on the index, a second delay element, and a third delay element, wherein the first delay element indicates a cause of a delay time in the target block, the second delay element indicates a threshold value of a delay time acceptable to the target block, and the third delay element indicates a delay pattern related to a tendency of delay times occurring in the target block.

### BRIEF DESCRIPTION OF THE DRAWINGS

Embodiments of the inventive concept will be more clearly understood from the following detailed description taken in conjunction with the accompanying drawings in which:

FIG. 1 is a diagram showing a debugging system according to an embodiment;

FIG. 2 is a diagram showing a serial interface circuit according to an embodiment;

FIG. 3A is a diagram showing a monitor block according to an embodiment;

FIG. 3B is a diagram showing the configuration of the monitor block according to an embodiment;

FIG. 4 is a flowchart of a method of operating a debugging system, according to an embodiment;

FIG. 5A is a diagram showing an example of a LUT according to an embodiment;

FIG. 5B is a diagram showing an example of an index-to-delay time measurement value graph in the LUT of FIG. 5A;

FIG. 6 is a flowchart of a method of operating a debugging system, according to an embodiment;

FIG. 7 is a flowchart of a method of operating a debugging system, according to an embodiment;

FIG. 8 is a diagram showing an example of an index history generation operation according to an embodiment;

FIGS. 9A and 9B are diagrams showing an example of an index conversion operation according to an embodiment;

FIG. 10 is a graph showing comparison between bit-width usages according to an embodiment and a comparative example;

FIG. 11 is a diagram showing an example of a monitor block according to an embodiment; and

FIG. 12 is a diagram showing an example of an extended application of a monitor block according to an embodiment.

### DETAILED DESCRIPTION

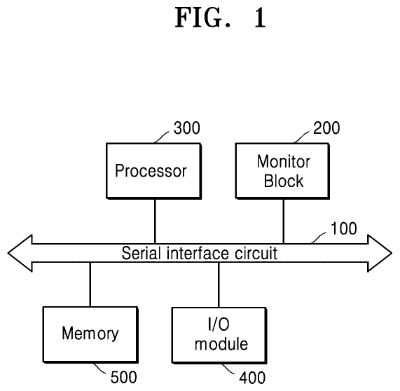

FIG. 1 is a diagram showing a debugging system according to an embodiment.

Referring to FIG. 1, the debugging system includes a serial interface circuit 100, a monitor block 200 (e.g., a monitoring circuit), a processor 300, an input/output (I/O) module 400 (e.g., an I/O circuit), and a memory 500.

The processor 300 may include circuits, interfaces, or program code for processing data and controlling operations of components of the debugging system. For example, the processor 300 may include a central processing unit (CPU), an advanced RISC machine (ARM), or an application specific integrated circuit (ASIC).

The input/output module 400 may receive video (e.g., dynamic image signals, still image signals, etc.), audio (e.g., voice signals, music signals, etc.), and additional information, etc. from external devices under the control by the processor 300. The input/output module 400 may include one of a high-definition multimedia interface (HDMI) port, a component jack, a personal computer (PC) port, and a universal serial bus (USB) port.

The memory 500 may include static random access memory (SRAM) or dynamic random access memory (DRAM) that stores data, commands, or program codes necessary for the operation of the debugging system. Also, the memory 500 may include a non-volatile memory. Program code that may operate to execute one or more operating systems and virtual machines (VMs) may be stored in the memory 500.

The serial interface circuit 100 may interconnect the processor 300, the input/output module 400, and the memory 500, and the processor 300. The input/output module 400, and the memory 500 may transmit and receive data through the serial interface circuit 100. For example, the input/output module 400 may transmit input audio data to the processor 300 through the serial interface circuit 100, and the processor 300 may transmit a control signal generated in response to the audio data back to the processor 300 through the serial interface circuit 100.

The serial interface circuit 100 may receive two or more input parallel signals from a transmission block and generate a serial signal by performing serialization on the received input parallel signals. The serial interface circuit 100 may transmit an amplified output serial signal to a reception block through one channel.

When an error occurs during the operation of the serial interface circuit 100, decoding is difficult due to the operation characteristics of the serial interface circuit 100. A delay time occurring in the serial interface circuit 100 may be measured to infer the internal state of the serial interface circuit 100 (i.e., to detect an error). However, as the size of the measured delay time increases, a bit-width needed to transmit and receive the measured delay time increases, thereby increasing the area of hardware used to detect an error. Also, due to the increase in the size of the measured delay time, it may be difficult to debug the serial interface circuit 100 based on a history of the measured delay times.

The monitor block 200 according to an embodiment is a monitor circuit electrically connected to the serial interface circuit 100 and may measure the delay time occurring in the serial interface circuit 100 to generate high resolution data such as delay time measurement value. The monitor block 200 may convert the delay time measurement value to low resolution data such as an index based on a look-up table (LUT) according to control information received from a control module of the serial interface circuit 100 and transmit the index to the control module of the serial interface circuit 100.

Therefore, according to an embodiment device, the index (low resolution data) is used instead of the delay time measurement value (high resolution data) to detect an error in the serial interface circuit 100 or for debugging the serial interface circuit 100, thereby preventing device performance degradation due to data overhead and maximizing data transmission/reception efficiency.

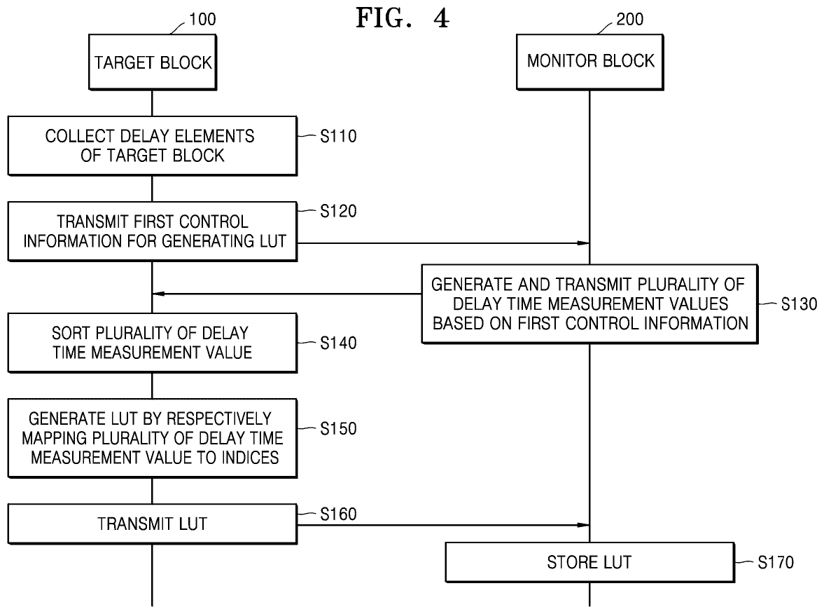

Furthermore, according to embodiments of devices and a methods presented herein, rapid error correction may be performed in the serial interface circuit 100 by increasing debugging accuracy by utilizing index history. Detailed descriptions thereof will be given below with reference to FIGS. 4 to 10.

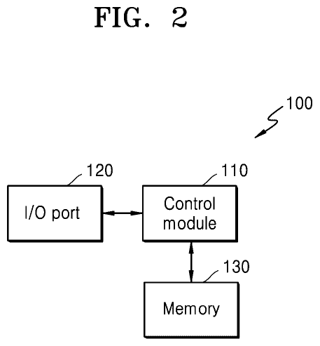

FIG. 2 is a diagram showing a serial interface circuit according to an embodiment.

Referring to FIG. 2, the serial interface circuit 100 includes a control module (e.g., a hardware manager) 110, an input/output port 120, and memory 130.

The input/output port 120 may receive data from a plurality of blocks (or various paths) and transmit data to a plurality of blocks (or various paths). The input/output port 120 may include a serializer (e.g., a serializer circuit) that generates output data by serializing a plurality of pieces of data input in parallel. For example, the input/output port 120 may receive an index or index history converted based on a LUT from the monitor block 200.

The memory 130 stores data such as basic programs, application programs, and setting information for the operation of the serial interface circuit 100. The memory 130 may include a register, a volatile memory, a non-volatile memory, or a combination of a volatile memory and a non-volatile memory. The memory 130 may provide stored data to the control module 130 according to a request of the control module 110.

The control module 110 may control overall operations of the serial interface circuit 100. For example, the control module 110 transmits and receives signals through the input/output port 120. Also, the control module 110 writes and reads data to and from the memory 130. Also, the control module 110 may perform functions for debugging errors that occur during the operation of the serial interface circuit 100 (e.g., a LUT generation function to generate LUT, a delay time measurement requesting function to request measurement of a delay time, etc.). To this end, the control module 110 may include a logic circuit, at least one processor or micro-processor or may be a part of a processor. According to an embodiment, the control module 110 controls the serial interface circuit 100 to perform operations according to embodiments described below (operations of FIGS. 4, 6, and 7).

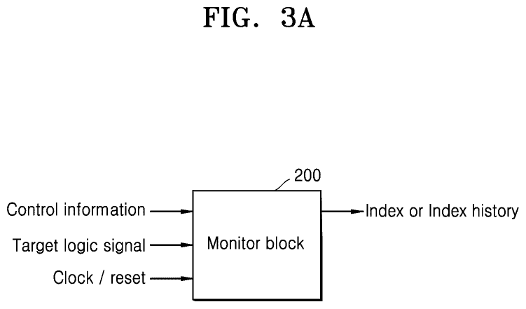

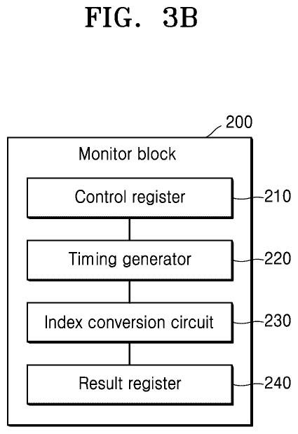

FIG. 3A is a diagram showing a monitor block according to an embodiment.

In detail, FIG. 3A shows signals input/output to/from the monitor block 200.

Referring to FIG. 3A, the monitor block 200 may receive control information, a target logic signal, and clock/reset signals and output an index or index history.

The monitor block 200 may receive control information from the serial interface circuit 100 (or the control module 110 of the serial interface circuit 100, FIG. 2). For example, the control information may include information indicating a target logic signal and any one of first to third control information. The first control information is control information for generating an LUT and may include a delay time measurement request in the serial interface circuit 100 based on the cause of a delay time of the serial interface circuit 100 (hereinafter referred to as a ‘first delay element’ of the serial interface circuit 100) and setting information for the monitor block 200 based on the delay time measurement request (i.e., setting information regarding components of the monitor block 200. For example, as shown in FIG. 3B, the components of the monitor block 200 may include a control register 210, a timing generator 220, an index conversion circuit 230, and a result register 240. Second control information is control information for debugging errors occurring in the serial interface circuit 100 and may include a delay time measurement request in the serial interface circuit 100 based on the first delay element (or a request for an index corresponding to a delay time measurement value), a measurement period for the delay time, and setting information regarding the monitor block 200 according to the delay time measurement request (or a request for an index corresponding to a delay time measurement value). The third control information is control information for debugging errors occurring in the serial interface circuit 100 and may include a delay time measurement request in the serial interface circuit 100 based on the first delay element (or an index history request), a measurement period for the delay time, and setting information regarding the monitor block according to the delay time measurement request (or an index history request).

The monitor block 200 may receive a target logic signal from logic of the serial interface circuit 100. The target logic signal refers to a target signal for measuring a delay time in the monitor block 200. The target logic signal may be designated through control information received from the control module 110 of the serial interface circuit 100.

The monitor block 200 may receive clock/reset signals to measure the delay time from the target logic signal. The monitor block 200 may count the delay time by synchronizing the target logic signal to a clock signal. For example, the monitor block 200 may count the target logic signal based on the clock signal to generate the delay time.

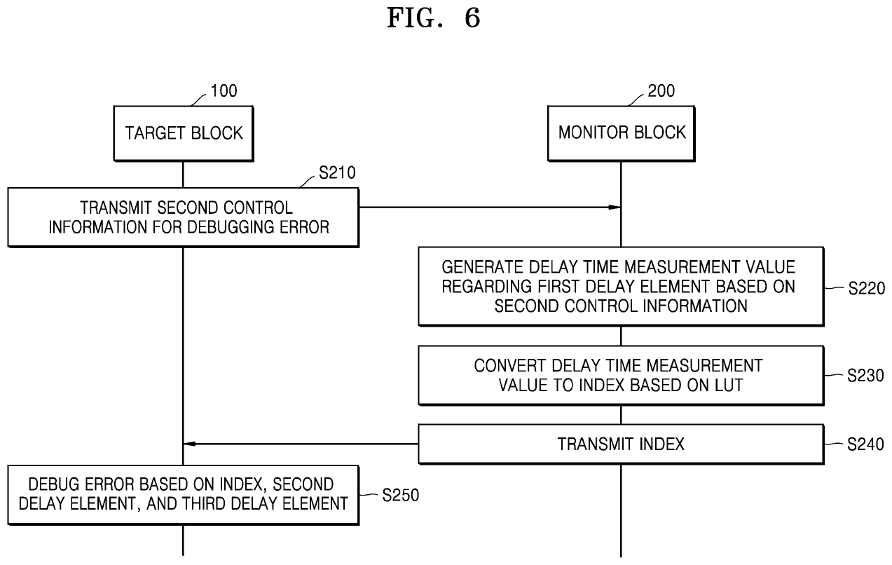

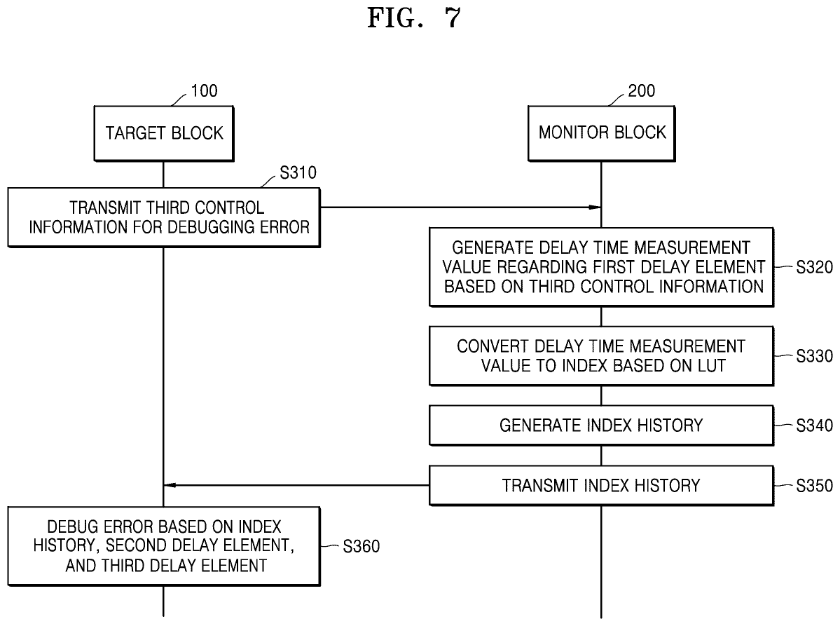

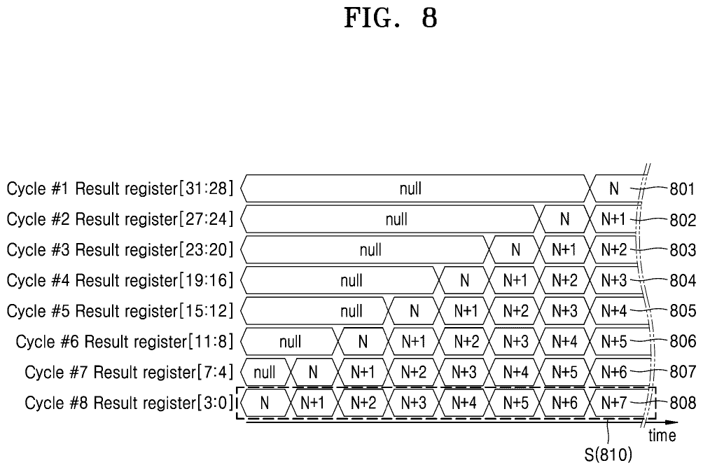

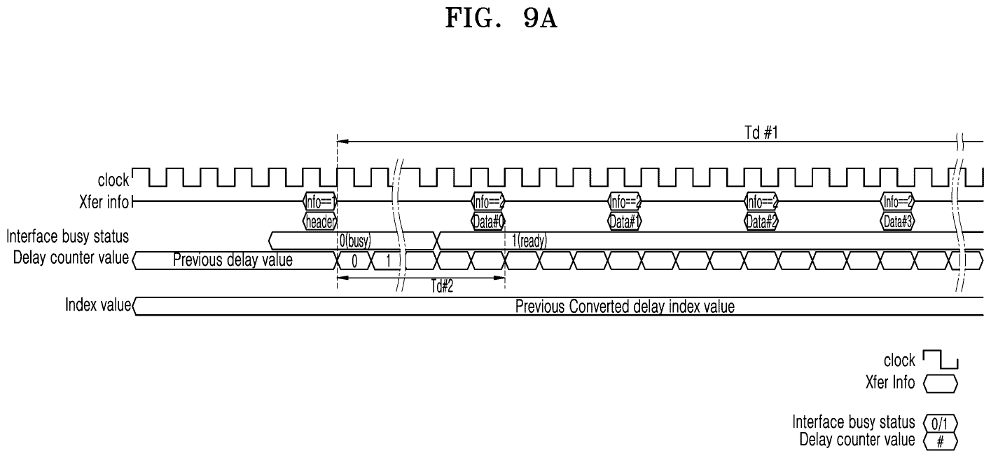

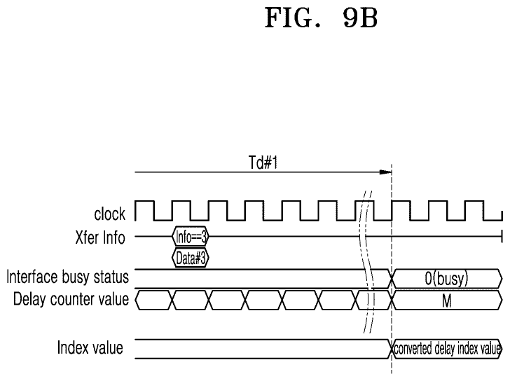

The monitor block 200 may transmit an index or an index table to the control module 110 of the serial interface circuit 100 based on the received control information. The monitor block 200 may convert a delay time measurement value into an index based on the LUT. A detailed embodiment thereof will be described below with reference to FIGS. 6, 9A, and 9B. The monitor block 200 may transmit index history generated by accumulating a plurality of indexes converted based on the LUT for a plurality of cycles to the control module 110 of the serial interface circuit 100. A detailed embodiment thereof will be described below with reference to FIGS. 7 and 8.

FIG. 3B is a diagram showing the configuration of a monitor block according to an embodiment.

Referring to FIG. 3B, the monitor block 200 may include the control register 210, the timing generator 220, the index conversion circuit 230, and the result register 240.

The control register 210 may receive control information (refer to FIG. 3A) from the control module 110 (FIG. 2) of the serial interface circuit 100. For example, the control module 110 (FIG. 2) of the serial interface circuit 100 may transmit control information regarding the monitor block 200 to the control register 210 through a software (SW) Config register.

The timing generator 220 includes a counter and may measure the delay time in the target logic signal (refer to FIG. 3A) using the counter. For example, the counter of the timing generator 220 may count the delay time by synchronizing the target logic signal (refer to FIG. 3A) to the clock signal. For example, the timing generator 220 may physically measure a linear delay time from the target logic signal based on the clock signal.

The index conversion circuit 230 may store an LUT generated considering the characteristics (e.g., a delay element) of the serial interface circuit 100. The index conversion circuit 230 converts a delay time measurement value (e.g., a measured linear delay time value) received from the timing generator 220 into an index (e.g., a non-linear index) based on the LUT. In an embodiment, the average data size of the index is smaller than the average data size of its corresponding delay time measurement value.

The result register 240 may store an index received from the index conversion circuit 230 for a predetermined period of time. The result register 240 may transmit an index or index history to the serial interface circuit 100.

The control register 210 may drive components included in the serial interface circuit 100 (e.g., the timing generator 220, the index conversion circuit 230, and the result register 240) based on control information (refer to FIG. 3A).

According to an embodiment, the control register 210 generates a plurality of delay time measurement values by measuring delay times regarding a target logic signal by driving the timing generator 220 according to the first control information and transmits the plurality of generated delay time measurement values to the serial interface circuit 100. The control module 110 (FIG. 2) of the serial interface circuit 100 may generate an LUT by sorting the plurality of delay time measurement values and mapping indices to a plurality of sorted delay time measurement values, respectively.

According to an embodiment, the control register 210 generates a delay time measurement value by driving the timing generator 220 according to the second control information. For example, the control register 210 may drive the timing generator 220 to measure a delay time in a target logic signal during a measurement period indicated by the second control information. The control register 210 may drive the index conversion circuit 230 according to the second control information to convert a delay time measurement value into an index based on the LUT. The control register 210 may store an index in the result register 240 according to the second control information and transmit the stored index to the control module 110 (FIG. 2) of the serial interface circuit 100. The control module 110 of the serial interface circuit 100 may debug errors in the serial interface circuit 100 based on indices such as the index received from the control register 210.

According to an embodiment, the control register 210 generates a delay time measurement value by driving the timing generator 220 according to the third control information. For example, the control register 210 may driver the timing generator 220 to measure a delay time in a target logic signal during a measurement period instructed by the third control information. The control register 210 may drive the index conversion circuit 230 according to the third control information. For example, the control register may drive the index conversion circuit 230 to convert a delay time measurement value into an index based on the LUT. The control register 210 may generate an index history by accumulating and storing indices in the result register 240 in a first-in-first-out (FIFO) manner for a plurality of cycles according to the third control information and transmit a generated index history to the control module 110 (FIG. 2) of the interface circuit 100. The control module 110 of the serial interface circuit 100 may debug errors in the serial interface circuit 100 based on the generated index history.

According to the monitor block 200, the serial interface circuit 100, and a method of operating the debugging system according to various embodiments, an LUT for converting a delay time measurement value (high resolution data) into an index (low resolution data) may be generated.

According to the monitor block 200, the serial interface circuit 100, and a method of operating the debugging system according to various embodiments, indices (low-resolution data) generated based on an LUT are used in the debugging process, thereby preventing the deterioration of device performance due to data overhead and maximizing data transmission and reception efficiency.

Furthermore, according to the monitor block 200, the serial interface circuit 100, and a method of operating the debugging system according to various embodiments, error correction may be rapidly performed by increasing debugging accuracy by utilizing an index history.

FIG. 4 is a flowchart of a method of operating a debugging system, according to an embodiment.

Referring to FIG. 4, a method of generating an LUT based on communications between a target block (e.g., the serial interface circuit 100) and the monitor block 200 in a debugging system may include operations S110 to S170. In FIG. 4, the target block may be the serial interface circuit 100 of FIG. 2.

In operation S110, the control module 110 of the target block (e.g., the serial interface circuit 100) collects delay elements of the target block. Here, the delay elements may include a first delay element regarding the cause of a delay time in the target block (e.g., the serial interface circuit 100), a second delay element regarding a threshold value of a delay time acceptable to the target block (e.g., the serial interface circuit 100), and a third delay element regarding a delay pattern indicating a tendency of delay time occurring in the target block (e.g., the serial interface circuit 100). The control module 110 of the target block (e.g., serial interface circuit 100) may list-up collected delay elements. The delay elements may be collectively referred to as a delay metric associated with an unacceptable delay that occurs in the serial interface circuit 100 such as the specific factors that caused the unacceptable delay (e.g., first control information), an amount of delay in the serial interface circuit 100 that is considered acceptable (e.g., second control information), and a pattern of delay time variations that occurs in the serial interface circuit 100 (e.g., third control information). The control module 110 of the target block may load or retrieve the delay metric from memory 130.

In operation S120, the control module 110 of the target block (e.g., the serial interface circuit 100) transmits first control information for generating an LUT to the monitor block 200. For example, the control module 110 of the target block (e.g., the serial interface circuit 100) may transmit the first control information to the monitor block 200 through a SW Config register. Here, the first control information may include a delay time measurement value request for generating the LUT based on the first delay element regarding the cause of the delay time in the serial interface circuit 100 and setting information according to the delay time measurement value request. Here, the cause of delay time is information included in the first delay element and may include first to fourth causes. For example, a first cause may be a signal transmission (e.g., 16 cycle delay occurs) according to the floorplan characteristics of the serial interface circuit 100, a second cause may be feedback reception from the serial interface circuit 100 (e.g., minimum 32 cycle delay occurs), a third cause may be signal conversion based on a fast Fourier transform (FFT) in the serial interface circuit 100 (e.g., 64 to 2048 cycle delay occurs), and a fourth cause may be a bus delay in the data reception block (e.g., a delay of 2 to 4 multiples of 50 μs occurs). For example, the control module 110 of the serial interface circuit 100 may request a delay time measurement value obtained by measuring and summing the delay times for each of the first to fourth causes described above and transmit the first control information including setting information regarding the monitor block 200 according to the delay time measurement value request to the monitor block 200.

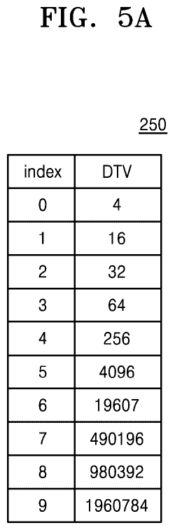

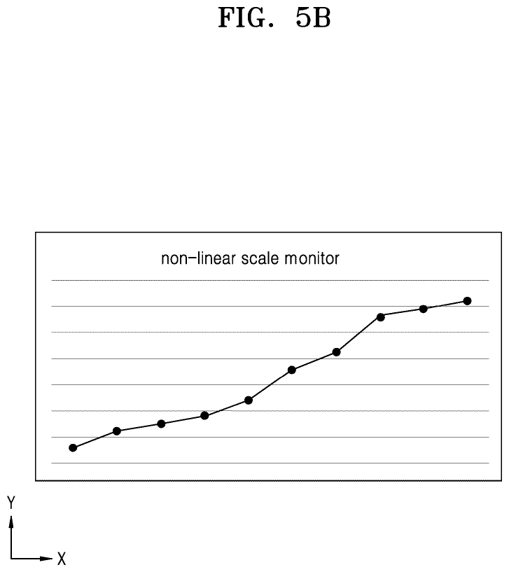

In operation S130, the monitor block 200 generates and transmit a plurality of delay time measurement values based on the first control information. For example, the control register 210 (FIG. 3B) of the monitor block 200 may drive the timing generator 220 (FIG. 3B) according to the first control information, measure a delay time for each of the first to fourth causes in the serial interface circuit 100, and sum the measured delay times for the first to fourth causes to generate a delay time measurement value. For example, the control register 210 (FIG. 3B) of the monitor block 200 may drive the timing generator 220 (FIG. 3B) according to the first control information to generate a plurality of delay time measurement values (e.g., DTVs 4, 16, 32, . . . , 64, 980392, 1960784 of FIG. 5A) by repeating measurement and summing of delay times for the first to fourth causes. For example, referring to FIGS. 4 and 5A, the plurality of delay time measurement values may include first to tenth delay time measurement values. For example, a first delay time measurement value may be ‘4’ in a first cycle, a second delay time measurement value may be ‘32’ in a second cycle, and a third delay time measurement value may be ‘4096’ in a third cycle. The control register 210 (FIG. 3B) of the monitor block 200 may transmit a plurality of the generated delay time measurement values to the control module 110 of the target block (e.g., serial interface circuit 100).

In operation S140, the control module 110 of the target block (e.g., serial interface circuit 100) sorts the plurality of delay time measurement values. For example, the control module 110 of the target block (e.g., serial interface circuit 100) may sort the plurality of delay time measurement values received from the monitor block 200 in ascending or descending order according to the size or magnitude of the delay time measurement values.

In operation S150, the control module 110 of the target block (e.g., the serial interface circuit 100) generates an LUT by mapping the plurality of delay time measurement values to indices, respectively. In operation S160, the control module 110 of the target block (e.g., serial interface circuit 100) transmits the LUT to the monitor block 200.

In operation S170, the monitor block 200 stores the LUT received from the control module 110 of the target block (e.g., the serial interface circuit 100) in the index conversion circuit 230 (FIG. 3B).

FIG. 5A is a diagram showing an example of the LUT according to an embodiment.

In detail, FIG. 5A shows an example of an LUT 250 generated in operation S160 of FIG. 4.

Referring to FIG. 5A, the LUT 250 includes a plurality of indices and a plurality of delay time measurement values (DTVs). In the LUT 250, a plurality of indices and a plurality of DTVs may respectively correspond to each other. Here, a DTV may mean a value obtained by measuring the delay time for each cause of delay time (e.g., the first to fourth causes of FIG. 4) during one cycle and summing delay times measured for each of the first to fourth causes. For example, a first DTV in a first cycle may be ‘4’, a second DTV in a second cycle may be ‘32’, a third DTV in a third cycle may be ‘4096’, a fourth DTV in a fourth cycle may be ‘64’, a fifth DTV in a fifth cycle may be ‘256’, a sixth DTV in a sixth cycle may be ‘16’ in a sixth cycle, a seventh DTV in a seventh cycle may be ‘19607’, an eighth DTV in an eighth cycle may be ‘490196’, a ninth DTV in a ninth cycle may be ‘980392’, and a tenth DTV in a tenth cycle may be ‘1960784’.

The control module 110 (FIG. 2) of the serial interface circuit 100 may sort the plurality of DTVs in ascending (or descending) order according to the size of the plurality of DTVs. For example, the control module 110 of the serial interface circuit 100 may sort the plurality of DTVs (in ascending order according to the size of the DTVs) as ‘4, 16, 32, 64, 256, 4096, 19607, 490196, 980392, 1960784’.

The control module 110 of the serial interface circuit 100 may generate the LUT 250 by mapping the plurality of sorted DTVs to indices, respectively. For example, the control module 110 of the serial interface circuit 100 may map a DTV ‘4’ to an index ‘0’, map a DTV ‘16’ to an index ‘1’, map a DTV ‘32’ to an index ‘2’, map a DTV ‘64’ to an index ‘3’, map a DTV ‘256’ to an index ‘4’, map a DTV ‘4096’ to an index ‘5’, map a DTV ‘19607’ to an index ‘6’, map a DTV ‘490196’ to an index ‘7’, map a DTV ‘980392’ to an index ‘8’, and map a DTV ‘1960784’ to an index ‘9.

Although FIG. 5A shows that, for convenience of explanation, a plurality of DTVs are sorted in ascending order, the inventive concept is not limited thereto. The control module 110 of the serial interface circuit 100 according to an embodiment of the inventive concept may sort a plurality of DTVs according to various sorting schemes.

FIG. 5B is a diagram showing an example of an index-to-DTV graph in the LUT of FIG. 5A.

In FIG. 5B, the horizontal axis x may represent indices, and the vertical axis y may represent DTVs. However, the vertical axis y may represent the logarithmic scale [log 10 (DTV)] of the DTVs.

Referring to FIGS. 5A and 5B, a plurality of DTVs do not show any regularity as the index increases, thus exhibiting non-linear characteristics (e.g., non-linear scale monitor).

The control module 110 of the serial interface circuit 100 according to an embodiment generates the LUT 250 by omitting/eliminating less important values (e.g., 5 to 15, 17 to 31, 33 to 63, etc.) (compression of information) and mapping highly important values (e.g., 4, 16, 32, 64, . . . , 1960784) to indices as the plurality of DTVs, based on the non-linear characteristics of a plurality of DTVs. For example, if the system concludes that a measured DVT is not indicative of an error, it can remove it from an existing LUT or create a new LUT that does not include an entry mapping the DTV to an index. For example, if there is a first LUT that includes an entry for this DVT, it can be compressed by removing this entry or a second LUT can be created that does not include this entry, which is smaller than the first LUT.

Therefore, according to a device and a method according to an embodiment, the index (low resolution data) is used instead of the delay time measurement value (high resolution data) during a debugging process by using the LUT 250, thereby preventing device performance degradation due to data overhead and maximizing data transmission/reception efficiency.

Also, a device and a method according to embodiments may increase debugging accuracy by utilizing an index history generated by accumulating/storing converted indices (low resolution data) for a plurality of cycles.

FIG. 6 is a flowchart of a method of operating a debugging system, according to an embodiment.

In detail, FIG. 6 is a diagram illustrating a method of debugging an error based on indices of an LUT when an error occurs in a target block (e.g., the serial interface circuit 100). Descriptions identical to those given above with reference to FIG. 4 will be omitted.

Referring to FIG. 6, a method of debugging an error based on indices of an LUT may include operations S210 to S250. The target block 100 of FIG. 6 may be the serial interface circuit 100 of FIG. 2.

In operation S210, the control module 110 of the target block (e.g., the serial interface circuit 100) transmits second control information for debugging an error to the monitor block 200.

For example, the control module 110 of the target block (e.g., the serial interface circuit 100) may transmit the second control information to the monitor block 200 through a SW Config register. Here, the second control information may include a delay time measurement value request for debugging an error based on the first delay element in the serial interface circuit 100 and setting information according to the delay time measurement value request. For example, the serial interface circuit 100 may set any one of first to fourth measurement periods as the measurement period for the delay time in the second control information. The first measurement period may refer to the period from a time point at which transmission of all data starts (e.g., a time point of completion of transmission of a data header) in the serial interface circuit 100 to a time point of completion of the transmission of all data. The second measurement period may refer to the period from a time point at which transmission of one piece of data starts to a time point of completion of transmission of the one piece of data. The third measurement period may refer to the period from a time point of completion of a last data transmission in the serial interface circuit 100 to a time point of reception of a reception completion message from a reception module. The fourth measurement period may refer to the period from the time point at which transmission of all data starts (e.g., a time point of completion of transmission of a data header) in the serial interface circuit 100 to the time point of reception of the reception completion message from the reception module.

In operation S220, the monitor block 200 generates delay time measurement values for the first delay element based on the second control information. For example, the control register 210 (FIG. 3B) of the monitor block 200 may drive the timing generator 220 (FIG. 3B) according to the second control information to measure a delay time for each of the first to fourth causes in the serial interface circuit 100, and sum the measured delay times for the first to fourth causes to generate a delay time measurement value. The timing generator 220 may transmit the generated delay time measurement values to the index conversion circuit 230 (FIG. 3B).

In operation S230, the monitor block 200 may convert the delay time measurement values (high resolution data) into indices (low resolution data) based on the LUT (e.g., refer to FIG. 5A). For example, the control register 210 (FIG. 3B) of the monitor block 200 may drive the index conversion circuit 230 (FIG. 3B) according to the second control information to convert the delay time measurement values into indices based on the LUT. In an embodiment, the average data size of indices is smaller than the average data size of delay time measurement values. The index conversion circuit 230 may transmit the converted indices to the result register 240 (FIG. 3B).

In operation S240, the monitor block 200 transmits indices to the control module 110 of the target block (e.g., the serial interface circuit 100). For example, the control register 210 (FIG. 3B) of the monitor block 200 may drive the result register 240 (FIG. 3B) according to the second control information to transmit stored indices to the control module 110 of the target block (e.g., the serial interface circuit 100). For example, the monitor block 200 may transmit stored indices to the control module 110 of the target block (e.g., the serial interface circuit 100) through an Advanced Peripheral Bus (APB) or an APB register.

In operation S250, the control module 110 of the target block (e.g., the serial interface circuit 100) performs error debugging based on indices, the second delay element, and the third delay element. Here, the second delay element may mean a threshold value of delay time acceptable to the serial interface circuit 100, and the third delay element may mean a delay pattern occurring in the serial interface circuit 100. The second delay element may be determined based on the operation unit time of the serial interface circuit 100.

The delay pattern may be a propagation delay pattern, a clock skew pattern, a jitter pattern, a setup and hold time violation pattern, or an inter-symbol interference (ISI) pattern. The propagation delay pattern may indicate the time it takes for a signal to travel from one point in a circuit to another. The clock skew pattern may indicate a discrepancy in the arrival times of clock signals at different parts of the circuit. The jitter pattern may indicate a variability in the timing of signal transitions. The setup and hold time violation pattern may indicate a failure to maintain stable data signals before (setup time) and after (hold time) of the clock edge. The inter-symbol interference (ISI) pattern may indicate overlapping of signals from adjacent bits, which occurs when the signal from a previous bit interferes with the signal of a current bit.

FIG. 7 is a flowchart of a method of operating a debugging system, according to an embodiment.

In detail, FIG. 7 is a diagram illustrating a method of debugging an error based on an index history when an error occurs in a target block (e.g., the serial interface circuit 100). Descriptions identical to those given above with reference to FIG. 4 or 6 will be omitted.

Referring to FIG. 7, a method of debugging an error based on an index history may include operations S310 to S360. The target block 100 of FIG. 7 may be the serial interface circuit 100 of FIG. 2.

In operation S310, the control module 110 of the target block (e.g., the serial interface circuit 100) transmits third control information for debugging an error to the monitor block 200. For example, the control module 110 of the target block (e.g., the serial interface circuit 100) may transmit the third control information to the monitor block 200 through a SW Config register. Here, the third control information may include a delay time measurement value request for debugging an error based on the first delay element in the serial interface circuit 100 and setting information according to the delay time measurement value request. For example, the serial interface circuit 100 may set any one of first to fourth measurement periods as the measurement period for the delay time in the third control information. The first measurement period may refer to the period from a time point at which transmission of all data starts (e.g., a time point of decoding of a data header) in the serial interface circuit 100 to a time point of completion of the transmission of all data. The second measurement period may refer to the period from a time point at which transmission of one piece of data starts to a time point of completion of transmission of the one piece of data. The third measurement period may refer to the period from a time point of completion of last data transmission in the serial interface circuit 100 to a time point of reception of a reception completion message from a reception module. The fourth measurement period may refer to the period from the time point at which transmission of all data starts (e.g., a time point of completion of transmission of a data header) in the serial interface circuit 100 to the time point of reception of the reception completion message from the reception module.

In operation S320, the monitor block 200 generates delay time measurement values for the first delay element based on the third control information. For example, the control register 210 (FIG. 3B) of the monitor block 200 may drive the timing generator 220 (FIG. 3B) according to the third control information to measure a delay time for each of the first to fourth causes in the serial interface circuit 100, and sum the measured delay times for the first to fourth causes to generate a delay time measurement value. The timing generator 220 may transmit the generated delay time measurement values to the index conversion circuit 230 (FIG. 3B).

In operation S330, the monitor block 200 converts the delay time measurement values (high resolution data) into indices (low resolution data) based on the LUT (e.g., refer to FIG. 5A). For example, the control register 210 (FIG. 3B) of the monitor block 200 may drive the index conversion circuit 230 (FIG. 3B) according to the third control information to convert the delay time measurement values into indices based on the LUT. For example, the average data size of indices may be smaller than the average data size of delay time measurement values. The index conversion circuit 230 may transmit the converted indices to the result register 240 (FIG. 3B).

In operation S340, the monitor block 200 generates an index history. For example, the control register 210 of the monitor block 200 may drive the result register 240 to generate an index history by accumulating and storing indices in a FIFO manner for a plurality of cycles according to the third control information. Here, the index history may include a current index, which is obtained by converting a delay time measurement value measured in a current cycle using an LUT, as well as at least one past index obtained by converting a delay time measurement value, which is measured in at least one previous cycle, by using the LUT.

In operation S350, the monitor block 200 transmits the index history to the control module 110 of the target block (e.g., the serial interface circuit 100). For example, the control register 210 (FIG. 3B) of the monitor block 200 may drive the result register 240 (FIG. 3B) according to the third control information to transmit a stored index history to the control module 110 of the target block (e.g., the serial interface circuit 100).

In operation S360, the control module 110 of the target block (e.g., the serial interface circuit 100) performs error debugging based on the index history, the second delay element, and the third delay element. Here, the second delay element may mean a threshold value of delay time acceptable to the serial interface circuit 100, and the third delay element may mean a delay pattern occurring in the serial interface circuit 100. The second delay element may be determined based on the operation unit time of the serial interface circuit 100. The threshold value may be the minimum or maximum delay time that the serial interface circuit 100 can tolerate while still operating correctly.

FIG. 8 is a diagram showing an example of an index history generation operation according to an embodiment.

In detail, FIG. 8 is a diagram illustrating an index history generation operation in the result register 240 (FIG. 3B) of the monitor block 200.

In FIG. 8, it is assumed that one slot in the result register 240 (FIG. 3B) includes a total of 32 bits from 0 to 31. However, the size of one slot is not limited thereto, and, in the result register 240 according to an embodiment, the size of one slot may vary.

In FIG. 8, it is assumed that the size of one index is 4 bits. However, the inventive concept is not limited thereto, and the size of one index according to an embodiment may vary. In FIG. 8, it is assumed that first to eighth cycles Cycle #1 to Cycle #8 are a plurality of consecutive cycles.

Referring to FIG. 8, the result register 240 may accumulate/store a plurality of indices converted based on the LUT for a plurality of cycles by using a shift register in the FIFO manner. For example, whenever it is changed to a next cycle, a new index (4 bits) converted in the next cycle may be added to the result register 240.

The index history according to an embodiment may include a current index obtained by converting a delay time measurement value measured in a current cycle using an LUT, and at least one past index obtained by converting a delay time measurement value, which is measured in at least one previous cycle, by using the LUT.

A first index N 801 obtained by converting a first delay time measurement value in a first cycle Cycle #1 is stored in [31:28] of the result register 240.

In a second cycle Cycle #2, which is a next cycle, the first index N 801 converted from the first delay time measurement value is shifted to [27:24] of the result register 240, and a second index N+1 802 converted from a second delay time measurement value is stored in [31:28] of the result register 240.

In a third cycle Cycle #3, which is a next cycle, the first index N 801 is shifted to [23:20] of the result register 240, the second index N+1 802 is shifted to [27:24] of the result register 240, and a third index N+2 803 converted from a third delay time measurement value is stored in [31:28] of the result register 240.

In a fourth cycle Cycle #4, which is a next cycle, the first index N 801 is shifted to [19:16] of the result register 240, the second index N+1 802 is shifted to [23:20] of the result register 240, the third index N+2 803 is shifted to [27:24] of the result register 240, and a fourth index N+3 804 converted from a fourth delay time measurement value is stored in [31:28] of the result register 240.

In a fifth cycle Cycle #5, which is a next cycle, the first index N 801 is shifted to [15:12] of the result register 240, the second index N+1 802 is shifted to [19:16] of the result register 240, the third index N+2 803 is shifted to [23:20] of the result register 240, the fourth index N+3 804 is shifted to [27:24] of the result register 240, and a fifth index N+4 805 converted from a fifth delay time measurement value is stored in [31:28] of the result register 240.

In a sixth cycle Cycle #6, which is a next cycle, the first index N 801 is shifted to [11:8] of the result register 240, the second index N+1 802 is shifted to [15:12] of the result register 240, the third index N+2 803 is shifted to [19:16] of the result register 240, the fourth index N+3 804 is shifted to [23:20] of the result register 240, the fifth index N+4 805 is shifted to [27:24] of the result register 240, and a sixth index N+5 806 converted from a sixth delay time measurement value is stored in [31:28] of the result register 240.

In a seventh cycle Cycle #7, which is a next cycle, the first index N 801 is shifted to [7:4] of the result register 240, the second index N+1 802 is shifted to [11:8] of the result register 240, the third index N+2 803 is shifted to [15:12] of the result register 240, the fourth index N+3 804 is shifted to [19:16] of the result register 240, the fifth index N+4 805 is shifted to [23:20] of the result register 240, the sixth index N+5 806 is shifted to [27:24] of the result register 240, and a seventh index N+6 807 converted from a seventh delay time measurement value is stored in [31:28] of the result register 240.

In an eighth cycle Cycle #8, which is a next cycle, the first index N 801 is shifted to [3:0] of the result register 240, the second index N+1 802 is shifted to [7:4] of the result register 240, the third index N+2 803 is shifted to [11:8] of the result register 240, the fourth index N+3 804 is shifted to [15:12] of the result register 240, the fifth index N+4 805 is shifted to [19:16] of the result register 240, the sixth index N+5 806 is shifted to [23:20] of the result register 240, the seventh index N+6 807 is shifted to [27:24] of the result register 240, and an eighth N+7 808 converted from an eighth delay time measurement value is stored in [31:28] of the result register 240.

The result register 240 may transmit a slot S 810 in which first to eighth indices N to N+7 to the control module 110 (FIG. 2) of the serial interface circuit 100 as the index history. The control module 110 (FIG. 2) of the serial interface circuit 100 may receive the index history (e.g., slot S 810), thereby obtaining an index converted in a current cycle (e.g., an eighth index N+7) as well as at least one index converted in at least one previous (past) cycle (e.g., first to seventh indices N to N+6 converted in total eight cycles) and utilizing them during a debugging process (e.g., utilizing them as the history of delay times that occurred in the serial interface circuit 100 during a plurality of cycles).

The control module 110 (FIG. 2) of the serial interface circuit 100 may perform debugging or error detection using the received index history (e.g., the slot S 810 in which first to eighth indices N to N+7 converted during total eight cycles are stored) the second delay element (the threshold value of the delay time acceptable to the serial interface circuit 100), and the third delay element (a delay pattern occurring in the serial interface circuit 100).

In a device and a method according to various embodiments, indices (low-resolution data) generated based on an LUT are used in a debugging process, thereby preventing the deterioration of device performance due to data overhead and maximizing data transmission and reception efficiency.

In a device and a method according to various embodiments, history information regarding the occurrence of a delay time in the serial interface circuit 100 may be obtained through a small number of communications (or data read-outs) by performing debugging based on an index history. Furthermore, in a device and a method according to various embodiments, rapid error correction may be performed by increasing debugging accuracy by utilizing index history.

In FIG. 8, for convenience of explanation, the slot S 810 in which a total of eight indices (e.g., the first to the eighth index N to N+7) are stored in the FIFO manner is described as an index history. However, the inventive concept is not limited thereto, and the index history according to an embodiment may be a slot in which various numbers of indices are stored in the FIFO manner according to the size and the setting of the result register 240.

FIGS. 9A and 9B are diagrams showing an example of an index conversion operation according to an embodiment.

In detail, FIGS. 9A and 9B are diagrams illustrating an operation in which, when the monitor block 200 receives the second control information or the third control information from the control module 110 of the serial interface circuit 100, the monitor block 200 measures delay times (i.e., generation of delay time measurement values) by using the timing generator 220 and converts generated delay time measurement values into indices through an LUT. Descriptions identical to those given above with reference to FIGS. 6 and 7 will be omitted.

In FIGS. 9A and 9B, xfer Info may indicate the characteristics of data included in a signal, and Interface busy status may indicate the operating state of the serial interface circuit 100 (e.g., ‘0’ for a busy state and ‘1’ for a ready state). Delay counter value may indicate delay time measurement values counted based on a clock signal by the timing generator 220, and the index value may indicate a value converted from a delay time measurement value based on the LUT by the index conversion circuit 230 (FIG. 3B).

Referring to FIGS. 9A and 9B, a signal transmitted from the serial interface circuit 100 may include a header, Data #0 to Data #N, and dummy data, and data included in the above- stated signal may be transmitted continuously or discontinuously according to the characteristics of the serial interface circuit 100.

The timing generator 220 may measure delay times in the serial interface circuit 100 during a measurement period Td #1 (e.g., the first measurement period of FIGS. 6 and 7) according to the second control information or the third control information, thereby generating delay time measurement values. Here, the measurement period Td #1 may mean the period from a time point of completion of transmission of the header to the time point of completion of transmission of dummy data during the period in which a signal is transmitted from the serial interface circuit 100. For example, the timing generator 220 may measure delay times for respective causes of delay times of the serial interface circuit 100 according to the second control information or the third control information and sum the measured delay times for the respective causes to generate delay time measurement values. The timing generator 220 may transmit the generated delay time measurement values to the index conversion circuit 230.

The index conversion circuit 230 may convert delay time measurement values (high resolution data) into indices (low resolution data) based on the LUT. For example, when a delay time measurement value is ‘M’ (here, it is assumed that M is ‘8’), the index conversion circuit 230 may convert the delay time measurement value ‘M’ into an index (or index value) ‘1’ based on the LUT (refer to FIG. 5A). The index conversion circuit 230 may transmit the index (or index value) ‘1’ to the result register 240, and the result register 240 may transmit the received index (or index value) ‘1’ to the control module 110 of the serial interface circuit 100. The control module 110 of the interface circuit 100 may debug an error occurring in the serial interface circuit 100 based on the received index (or index value) ‘1’.

Although it is described with reference to FIGS. 9A and 9B that the timing generator 220 measures a delay time with respect to a signal transmitted by the serial interface circuit 100 during a measurement period Td #1 (e.g., the first measurement period of FIGS. 6 and 7) according to the second control information or the third control information, the inventive concept is not limited thereto, and the timing generator 220 according to an embodiment may measure the delay time of the serial interface circuit 100 for various measurement periods (e.g., a measurement period TD #2 (e.g., the second measurement period of FIGS. 6 and 7)) according to the setting of the second control information or the third control information. Here, the measurement period Td #2 may mean the period from a time point at which transmission of one piece of data (e.g., Data #0) starts to a time point of completion of the transmission of one piece of data.

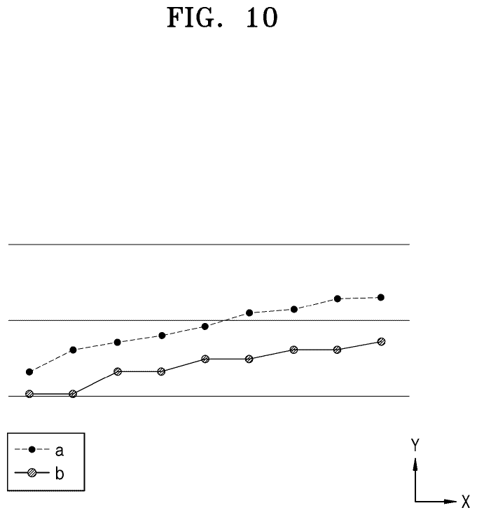

FIG. 10 is a graph showing comparison between bit-width usages according to an embodiment and a comparative example.

In FIG. 10, the horizontal axis x may represent a delay time measurement value a or an index b, and the vertical axis y may represent bit-width usage.

Referring to FIG. 10, the graph a may represent a bit-width usage graph according to an increase in the delay time measurement value according to a comparative example, and the graph b may represent a bit-width usage graph according to an increase in the index according to an embodiment.

In the graph a, it may be seen that, as the delay time measurement value increases, the bit-width usage needed for transmission of the delay time measurement value increases rapidly (compared to that of the graph b).

On the other hand, in the graph b, it may be seen that, even when a converted index value increases as the delay time measurement value increases, the bit-width usage needed for transmission of an index gradually increases (compared to that of the graph a).

Therefore, as described above, in a device and a method according to an embodiment, even when the delay time measurement value increases, the delay time measurement value is converted to an index and transmitted/received, and thus the bit-width usage is low. Therefore, when a device and a method according to an embodiment is actually implemented as hardware, the hardware may be implemented/designed as a product with a small area (e.g., 1000 gate counts or less).

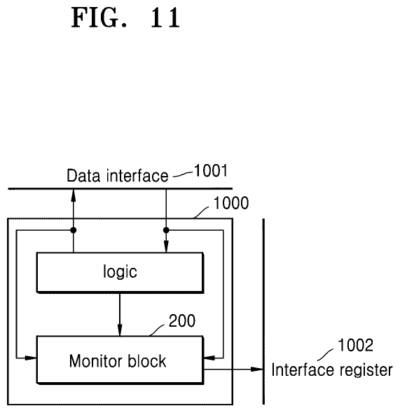

FIG. 11 is a diagram showing an example of a monitor block according to an embodiment.

Referring to FIG. 11, the monitor block 200 according to an embodiment may be implemented/designed to be close to a data interface 1001 (e.g., serial interface circuit 100) subjected to delay time measurement. For example, the monitor block 200 may be implemented/designed near to an input/output port of an interface controller 1000.

The monitor block 200 may be included in the interface controller 1000 and does not affect the control of an existing logic of the interface controller 1000. The monitor block 200 may obtain a target logic signal of the data interface 1001 (e.g., the serial interface circuit 100) through electrical connection with existing logic of the interface controller 1000. The monitor block 200 may measure a delay time of the target logic signal, generate a delay time measurement value, and convert the generated delay time measurement value into an index based on an LUT. The monitor block 200 may transmit the index to an interface register 1002 for debugging or detecting an error occurring in the data interface 1001 (e.g., serial interface circuit 100).

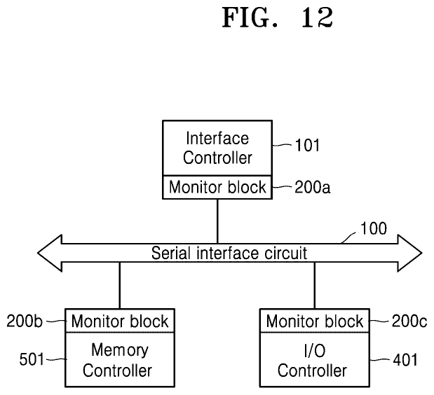

FIG. 12 is a diagram showing an example of an extended application of a monitor block according to an embodiment.

Referring to FIG. 12, the monitor block 200 according to an embodiment may be easily connected to existing logic or an existing port of a target block to be measured, and thus the monitor block 200 may be applied not only to the serial interface circuit 100 but also as monitor blocks (e.g., 200a, 200b, and 200c) for measurement of delay times in various blocks/devices. Further, the monitor block may be easily connected to input/output ports for existing signals. For example, the monitor block 200 according to an embodiment may be applied as a monitor block 200a for measuring a delay time in any interface block (or the interface controller 101), a monitor block 200b for measuring a delay time in a memory block (or a memory controller 501), and a monitor block 200c for measuring a delay time in an input/output block (or an input/output controller 401).

While the inventive concept has been particularly shown and described with reference to embodiments thereof, it will be understood that various changes in form and details may be made therein without departing from the spirit and scope of the following claims.

What is claimed is:

1. A serial interface circuit, comprising:
an input/output (I/O) port configured to receive data; and
a control circuit configured to load a delay metric for the serial interface circuit, transmit first control information of the delay metric to a monitor circuit to cause the monitor circuit to generate a plurality of delay time measurement values, sort the plurality of delay time measurement values to generate sorted values, generate a look-up table (LUT) by mapping the sorted values to indices and transmit the LUT to the monitor circuit.

2. The serial interface circuit of claim 1, wherein the delay metric comprises:
a first delay element regarding a cause of a delay time in the serial interface circuit;
a second delay element regarding a threshold value of a delay time acceptable to the serial interface circuit; and
a third delay element regarding a delay pattern representing a tendency of delay times occurring in the serial interface circuit.

3. The serial interface circuit of claim 2, wherein the first control information comprises a delay time measurement value request for generating the LUT based on the first delay element for the cause of the delay time occurring in the serial interface circuit and setting information regarding the monitor circuit according to the delay time measurement value request.

4. The serial interface circuit of claim 1, wherein the control circuit is configured to sort the plurality of delay time measurement values in ascending or descending order according to sizes of the plurality of delay time measurement values.

5. The serial interface circuit of claim 2, wherein the control circuit is configured to transmit second control information of the delay metric to cause the monitor circuit to measure a delay time in the serial interface circuit using the data, extract an index among the indices corresponding to the delay time, and debug an error based on the index, the second delay element, and the third delay element.

6. The serial interface circuit of claim 5, wherein the second control information comprises a delay time measurement value request for debugging the error based on the first delay element regarding a cause of a delay time occurring in the serial interface circuit, a measurement period for the delay time, and setting information regarding the monitor circuit according to the delay time measurement value request, and
the index means a value obtained by converting a delay time measurement value measured during the measurement period of the second control information using the LUT.

7. The serial interface circuit of claim 2, wherein the control circuit is further configured to transmit third control information of the delay metric to the monitor circuit when an error occurs in the serial interface circuit, receive an index history from the monitor circuit in response to the third control information, and debug the error based on the index history, the second delay element, and the third delay element.

8. The serial interface circuit of claim 7, wherein the third control information comprises a request for providing an index history for debugging the error based on the first delay element regarding a cause of a delay time occurring in the serial interface circuit, a measurement period for the delay time, and setting information regarding the monitor circuit according to the request for providing the index history, and
the index history comprises a current index obtained by converting a delay time measurement value measured in a current cycle using the LUT, and at least one past index obtained by converting a delay time measurement value measured in at least one previous cycle using the LUT.

9. A monitor circuit, comprising:
a timing generator;
an index conversion circuit;
a result register; and
a control register configured to drive the timing generator, the index conversion circuit, and the result register based on at least one piece of control information received from a serial interface circuit,
wherein, when first control information for generating a look-up table (LUT) is received, the control register drives the timing generator according to the first control information to generate a plurality of delay time measurement values and transmits the plurality of delay time measurement values to the serial interface circuit, and stores the LUT received from the serial interface circuit in the index conversion circuit, and
the LUT is generated by mapping the plurality of delay time measurement values to indices.

10. The monitor circuit of claim 9, wherein the first control information comprises a delay time measurement value request for generating the LUT based on a first delay element regarding a cause of a delay time occurring in the serial interface circuit and setting information regarding the monitor circuit according to the delay time measurement value request.

11. The monitor circuit of claim 9, wherein, when an error occurs in the serial interface circuit, the control register drives the timing generator, the index conversion circuit, and the result register according to second control information from the serial interface circuit,
the timing generator generates a delay time measurement value obtained by measuring a delay time occurring in the serial interface circuit based on the second control information and transmits the delay time measurement value to the index conversion circuit,
the index conversion circuit converts the delay time measurement value into an index based on the second control information and the LUT and transmits the index to the result register,
the result register transmits the index to the serial interface circuit based on the second control information, and
the error is debugged based on the index, a second delay element regarding a threshold value of a delay time acceptable to the serial interface circuit, and a third delay element regarding a delay pattern in the serial interface circuit.

12. The monitor circuit of claim 11, wherein the second control information comprises a delay time measurement value request for debugging the error based on the first delay element regarding a cause of a delay time occurring in the serial interface circuit, a measurement period for the delay time, and setting information regarding the monitor circuit according to the delay time measurement value request.

13. The monitor circuit of claim 9, wherein, when an error occurs in the serial interface circuit, the control register drives the timing generator, the index conversion circuit, and the result register according to third control information from the serial interface circuit,
the timing generator generates a delay time measurement value obtained by measuring a delay time occurring in the serial interface circuit based on the third control information and transmits the delay time measurement value to the index conversion circuit,
the index conversion circuit converts the delay time measurement value into an index based on the third control information and the LUT and transmits the index to the result register,
the result register is further configured to generate an index history by accumulating indices for a plurality of cycles based on the third control information and transmit the index history to the serial interface circuit, and
the error is debugged based on the index history, a second delay element regarding a threshold value of a delay time acceptable to the serial interface circuit, and a third delay element regarding a delay pattern in the serial interface circuit.

14. The monitor circuit of claim 13, wherein the third control information comprises a request for providing an index history for debugging the error based on the first delay element regarding a cause of a delay time occurring in the serial interface circuit, a measurement period for the delay time, and setting information regarding the monitor circuit according to the request for providing the index history.

15. The monitor circuit of claim 13, wherein the index history comprises a current index obtained by converting a delay time measurement value measured in a current cycle using the LUT, and at least one past index obtained by converting a delay time measurement value measured in at least one previous cycle using the LUT.

16. The monitor circuit of claim 15, wherein the at least one past index and the current index are stored in the index history according to a first in first out (FIFO) method.

17. A method of operating a debugging system, the method comprising:
generating a look-up table (LUT) based on a first delay element;
when an error occurs in a target block, measuring at least one delay time in the target block and generating a delay time measurement value based on the measured at least one delay time;
converting the delay time measurement value into an index based on the LUT; and
debugging an error based on the index, a second delay element, and a third delay element,
wherein the first delay element indicates a cause of a delay time in the target block,
the second delay element indicates a threshold value of a delay time acceptable to the target block, and
the third delay element indicates a delay pattern related to a tendency of delay times occurring in the target block.

18. The method of claim 17, wherein the generating of the LUT comprises:
generating a plurality of delay time measurement values based on the first delay element;
sorting the plurality of delay time measurement values in ascending or descending order according to sizes of the plurality of delay time measurement values to generate sorted values; and
generating the LUT by mapping the sorted values to indices.

19. The method of claim 17, further comprising:
generating an index history by accumulating indices converted based on the LUT for a plurality of cycles; and
debugging the error based on the index history, the second delay element, and the third delay element.

20. The method of claim 19, wherein the index history comprises a current index obtained by converting a delay time measurement value measured in a current cycle using the LUT, and at least one past index obtained by converting a delay time measurement value measured in at least one previous cycle using the LUT.
